(19) United States
(12) Patent Application Publication
(10) Pub. No.: US 2019/0274376 A1
(43) Pub. Date: Sep. 12, 2019

(54) Printable Heaters for Wearables and Other Articles

(71) Applicant: E I DU PONT DE NEMOURS AND COMPANY, Wilmington, DE (US)

(72) Inventors: WEIYING GAO, Landenberg, PA (US); Mehrdad Mehdizadeh, Avondale, PA (US); Mark Allan Lamontia, Landenberg, PA (US)

(21) Appl. No.: 15/915,470

(22) Filed: Mar. 8, 2018

(51) Int. Cl. A41D 13/005; H05K 1/02

(52) U.S. Cl. CPC A41D 13/0051; H05K 1/0201; H05B 2203/036; H05B 2203/007; H05K 2201/09245

(57) ABSTRACT

This invention provides improved printed heaters for use in articles such as wearable garments and seats. The improvement comprises replacing the single large area resistive material layer with columns of a number of small patches of resistive material or of continuous resistive material, i.e., replacing the single large area heater with a number of smaller individual heaters. A series of conductive strips across the columns render the heater more robust, less sensitive to local resistive area failure. Printing of the resistive material is facilitated since the area of each resistive material patch is greatly reduced. In addition, the embodiments enable the opportunity to provide a breathable heater.

### FIELD OF THE INVENTION

This invention is directed to improved printable heaters for wearable garments and other articles.

### BACKGROUND OF THE INVENTION

There is increasing interest in providing comfortable heated wearable garments Currently typical commercialized heated garments are powered via resistance wires. These garments have the advantage that the areas between the wires allow the fabric to breathe, but they have the disadvantage that the wires presence renders the garments uncomfortable.

An alternative is to use heaters with printed components that would provide greater comfort. In one such version, a component of the heater is a layer of resistive material, e.g., carbon, that serves as the resistive heating element between two bus bars. Such a layer could cover a significant portion of a garment. It is difficult to print a large area resistive material layer with appropriate thickness and uniformity using currently available compositions and the resulting heaters suffer from temperature non-uniformity during heating. One remedial approach is to provide columns of resistive material in parallel. The columns can consist of areas of resistive material connected by conductive material or by a continuous column of resistive material. However, the failure of the resistive material in a portion of either of these columns would eliminate the ability of the entire column to heat. There is a need for improved printed heaters.

### SUMMARY OF THE INVENTION

This invention provides an article containing a heater, the heater comprising:
a) a substrate;
b) two printed bus bars;
c) an array of printed resistive material areas of essentially the same shape arranged in columns between the two bus bars with spaces between adjacent resistive material areas in a column and with a separation between adjacent columns, wherein the first resistive material area in each column is contiguous to one bus bar and the last resistive material area in each column is contiguous to the other bus bar; and
d) an array of printed conductive material areas, wherein each printed conductive material area is positioned to fill the spaces between and overlap and be contiguous to adjacent pairs of resistive material areas in two or more columns, wherein there is a conductive material area in every space between resistive material areas in a column and wherein the conductive areas and the bus bars can be printed onto the substrate before or after the resistive material areas.
   The invention also provides an article containing a heater, the heater comprising:
a) a substrate;
b) two printed bus bars; and
c) an array of printed columns of resistive material between the two bus bars with a separation between adjacent columns, wherein the top of each column is contiguous to one bus bar and the bottom of each column is contiguous to the other bus bar; and
d) an array of printed rows of conductive material spaced at intervals across the columns, wherein the bus bars and the conductive material rows can be printed onto the substrate before or after the resistive material columns.

### BRIEF DESCRIPTION OF THE FIGURES

FIG. 1 illustrates an embodiment of a printed heater, the heater comprising a substrate with two parallel bus bars, an array of printed resistive material rectangles arranged in columns between the two bus bars with essentially identical spaces between adjacent resistive material rectangles in a column, and a separation between adjacent columns wherein the columns are orthogonal to the bus bars and the columns are essentially identical so that the rectangles and the spaces between them in the various columns form rows orthogonal to the columns. The heater also consists of an array of rows of printed electrically conductive material with a conductive row positioned to fill the space between, to overlap, and to be contiguous to an adjacent pair of resistive material rectangles in every column.

FIG. 2 shows details of FIG. 1, i.e., the individual rectangles of printed resistive material and the rows of conductive material across the columns as well as the separation between adjacent columns.

FIG. 3 shows columns of printed resistive material for use in another embodiment of a heater, the heater comprising a substrate with two parallel bus bars and an array of printed columns of resistive material between the bus bars and orthogonal to the bus bars.

FIG. 4 illustrates an embodiment of a printed heater, the heater comprising a substrate with two parallel bus bars, an array of printed columns of resistive material between the bus bars and orthogonal to the bus bars, and rows of conductive material orthogonal to the columns and spaced equidistant from one another and spanning all the columns. The resistive material columns are shown printed onto the substrate first followed by the rows of conductive material.

FIG. 5 illustrates an embodiment of a printed heater, the heater comprising a substrate with two parallel bus bars, an array of printed columns of resistive material between the bus bars and orthogonal to the bus bars, and rows of conductive material orthogonal to the columns and spaced equidistant from one another and spanning all the columns. The rows of conductive material are shown printed onto the substrate first followed by the resistive material columns.

### DETAILED DESCRIPTION OF THE INVENTION

The invention relates to an improved printed heater for use in wearable garments and other articles such as seats. The temperature non-uniformity and moisture vapor transport issues with printing large areas of resistive material are resolved by using an array of small areas of resistive material each of which serves as an individual heater instead of a single heater with a large area resistive material layer. The ability to print numerous smaller areas of resistive material results in more uniform areas of resistive material and therefore improved performance of the individual heaters and the heater comprising these individual heaters. The resistive material areas are arranged in columns with spaces between them or are continuous columns. The use of areas of conductive material to contact resistive areas in different columns addresses the problem of a failure of the resistive material in a portion of a column eliminating the ability of the entire column to heat.

In addition, when the substrate upon which the heater is printed is permeable, the heater has the additional advantage of being breathable in the sense that air and moisture, i.e., water vapor, can pass through the exposed regions of the permeable substrate in the separations between adjacent columns. This can provide additional comfort to the wearer of a garment. The wearable garment itself may be comprised of a permeable fabric upon which the heater is printed or the heater may be printed on a permeable polymer or permeable fabric substrate that is attached to the garment. In an embodiment the substrate is thermoplastic polyurethane.

### Array of Printed Resistive Material Areas Arranged in Columns

In this embodiment, the heater comprises a substrate, two printed bus bars, an array of printed resistive material areas arranged in columns between the two bus bars, with spaces between adjacent resistive material areas in a column and with a separation between adjacent columns, and an array of printed conductive material areas, wherein a conductive material area is positioned to fill the space between, to overlap, and to be contiguous to, i.e., to be in electrical contact with, adjacent pairs of resistive material areas in two or more columns, and wherein there is a conductive material area in every space between resistive material areas. The first resistive material area in each column is contiguous to, i.e., in electrical contact with, one bus bar and the last resistive material area in each column is contiguous to, i.e., in electrical contact with, the other bus bar. The heater does not contain interdigitated electrodes. The conductive areas and the bus bars can be printed onto the substrate before or after the resistive material areas. If the substrate is permeable, the exposed permeable substrate in the separations between adjacent columns renders the heater breathable.

In some embodiments, the printed conductive material areas and bus bars are silver areas and silver bus bars and the printed resistive material is carbon. In other embodiments, the printed conductive material areas and bus bars are copper areas and copper bus bars and the printed layer of resistive material is carbon. In still other embodiments, the printed conductive areas and bus bars are silver-silver chloride, gold or aluminum.

The electrically conductive areas and bus bars referred to herein are formed from polymer thick film pastes containing an electrical conductor. When the printed conductive material areas and bus bars are silver, they are formed using polymer thick film silver pastes. The resistive material is also printed using a polymer thick film paste. When the printed resistive material is printed carbon, it is formed using a polymer thick film carbon paste. When using polymer thick film pastes, the polymer is an integral part of the final composition, i.e., the conductive material, the bus bar and the resistive material.

The heater resistance R_{H} is a primary factor for determining the heater performance. R_{H} depends on a number of geometrical parameters in addition to the sheet resistance Rₛ of the resistive material. The geometrical parameters are the dimensions of the resistive material areas, the distances between the resistive areas in a column, the number of resistive areas in a column, and the number of columns. These parameters have design limitations dictated by the printing process and its limits of resolution as well as by the overall heater size.

In one embodiment, the array of printed resistive material areas are essentially the same shape and are arranged in parallel columns, wherein there are M resistive material areas in each column, wherein adjacent resistive material areas in each column are numbered i and i+1 in the same order, where i ranges from 1 to M−1, and wherein there are M−1 printed conductive material areas, wherein a printed conductive material area is positioned to fill each space between and overlap and be contiguous to the adjacent pair of resistive material areas i and i+1 in all the columns, where i ranges from 1 to M−1. The first resistive material area, number 1, in each column is contiguous to one bus bar and the last resistive material area, number=M, in each column is contiguous to the other bus bar.

In one such embodiment, the two printed bus bars are parallel, the columns of resistive areas are orthogonal to the bus bars and the columns are essentially identical so that the i^{th} resistive material areas in the various columns form a row as do the spaces above and below the resistive material areas and these rows are orthogonal to the columns. The M−1 printed conductive material areas are M−1 rows of printed conductor, each printed conductive material area with a width w greater than the space between adjacent resistive material areas so as to create overlap with the resistive material areas, and wherein the M−1 rows of printed conductor are orthogonal to the columns and a printed conductor row is positioned to overlap each row of spaces.

In one of the above embodiments, each individual resistive material area is in the form of a rectangle with width W and effective length L_{eff}. The effective length L_{eff} of the resistive material rectangle is the length of the resistive material between the overlapping contiguous conductive rows on the two sides of the resistive material rectangle. Each resistive material rectangle has essentially the same sheet resistance Rₛ and the spaces between the resistive material rectangles in a column are essentially identical. There are N columns and there is a separation d between adjacent columns. In one embodiment, d is between 0.3 and 10 times the width W of a resistive material rectangle. This embodiment will be discussed further with reference to the Figures.

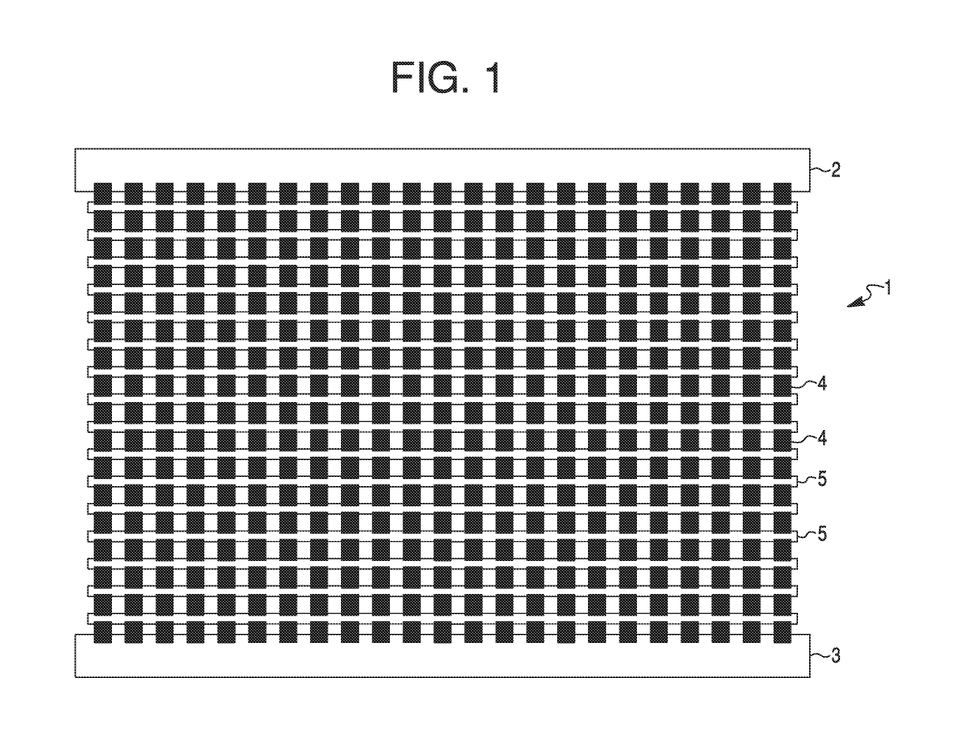

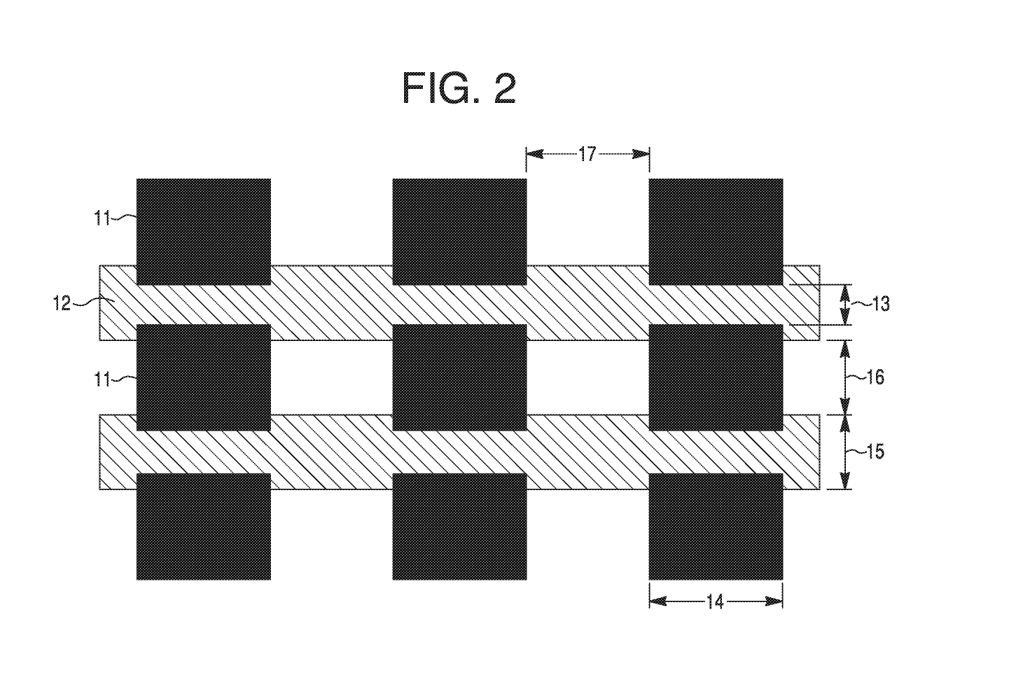

FIG. 1 illustrates the embodiment of a printed heater 1 described above. There are two parallel printed bus bars 2 and 3. There is an array of printed resistive material areas in the form of rectangles 4 arranged in parallel columns as shown in FIG. 1. The columns are essentially identical. There are spaces of length s between adjacent resistive material rectangles 4 in a column. There are M resistive material rectangles in a column. In the columns shown in FIG. 1 there are seventeen such resistive material rectangles, i.e., M=17 for FIG. 1. There are twentythree columns shown in FIG. 1, i.e., N=23. There is an array of rows 5 of printed conductive material. A conductive row 5 is positioned to fill the space between and overlap and be contiguous to every adjacent pair of resistive material rectangles 4 in all the columns, i.e., a given row of conductive material is positioned to fill the space between and overlap and be contiguous to every adjacent pair of resistive material rectangles i and i+1 in all the columns, where i ranges from 1 to M−1. As shown in FIG. 1, the bus bars 2 and 3 and the conductive rows 5 have been printed first and the resistive rectangles 4 printed second. This embodiment will be further discussed using the details shown in FIG. 2.

FIG. 2 shows nine resistive material rectangles 11, three in each of three adjacent columns. Also shown are electrically conductive areas in the form of rows 12. As shown in FIG. 2, the conductive rows 12 have been printed first and the resistive rectangles 11 printed second. The electrically conductive rows fill the space 13 (length s) between the resistive material rectangles as well as overlapping and being contiguous to the pair of adjacent resistive rectangles 11 in each column. The width W of the resistive material rectangles is indicated by 14. The width w of the conductive row is indicated by 15 and is greater than the space 13 so as to provide overlap with the pair of adjacent resistive rectangles and be contiguous to them. The effective length L_{eff} of the resistive material rectangle is indicated by 16. The distance d between columns is indicated by 17.

The resistance of each resistive material rectangle is R_{rect} and R_{rect}=Rₛ×L_{eff}/W. The resistive material rectangles in a column are electrically in series and, with M resistive material rectangles in a column, the column resistance R_{col}=R_{rect}×M. The N columns are electrically parallel so that the total heater resistance R_{H}=Rₛ (L_{eff} M)/(W N).

As an example, if the resistive material rectangle is a printed carbon rectangle with Rₛ=30 ΩQ/square and L_{eff}/W=0.67, R_{rect}=20Ω. If M=25 and N=50, R_{H}=10Ω. A 12-volt battery can supply about 14 Watts of power to the heater which is an appropriate amount for a wearable heater and for other articles with a R_{H} of about 10Ω.

As indicated previously, the failure of one of the resistive rectangles in a column would eliminate the ability of the entire column to heat were it not for the rows of conductive material connecting all the similar adjacent pairs of resistive material rectangles in all columns. If one of the resistive material rectangles fails and open-circuits, the adjacent conductive material rows carry the current around the failed resistive material rectangle. All the other resistive material rectangles in the column continue to heat.

### Array of Printed Columns of Resistive Material

In this embodiment, the heater comprises a substrate, two printed bus bars, an array of printed columns of resistive material between the two bus bars with a separation between adjacent columns, and an array of printed rows of conductive material spaced at intervals across the columns of resistive material. In contrast to the previous embodiment, the column of resistive material is continuous from one bus bar to the other, with no separations. The top of each column is contiguous to the one bus bar and the bottom of each bus bar is contiguous to the other bus bar. The heater does not contain interdigitated electrodes. The bus bars and the conductive rows can be printed onto the substrate before or after the resistive material columns. If the substrate is permeable, the exposed permeable substrate in the regions between adjacent columns renders the heater breathable.

In some embodiments, the printed conductive material rows and bus bars are silver rows and silver bus bars and the printed resistive material is carbon. In other embodiments, the printed conductive material rows and bus bars are copper rows and copper bus bars and the printed resistive material is carbon. In still other embodiments, the printed conductive rows and bus bars are silver-silver chloride, gold or aluminum.

As indicated above, the bus bars, the conductive material rows, and the resistive material columns referred to herein are formed from polymer thick film pastes.

The heater resistance is a primary factor, along with breathability, for determining the performance of the heater. R_{H} depends on a number of geometrical parameters in addition to the sheet resistance Rₛ of the resistive material. The geometrical parameters are the dimensions of the resistive material columns and the number of columns. These parameters have design limitations dictated by the printing process and its limits of resolution as well as by the overall heater size.

In one embodiment, the two printed bus bars are parallel, the columns of resistive material are orthogonal to the two bus bars; and the rows of conductive material are orthogonal to the columns of resistive material. In an embodiment the rows of conductive material are equidistant from one another. The top of each column is contiguous to, i.e., in electrical contact with, one bus bar and the bottom of each bus bar is contiguous to, i.e., in electrical contact with, the other bus bar.

Each individual resistive material column has a width W and a length L, the distance between the two bus bars. There are N columns and there is a separation d between adjacent columns. In one embodiment d is between 0.3 and 10 times the width W of a resistive column. There are P rows of conductive material each of width w. The effective length of the column for heating is L−Pw.

The resistance of each resistive material column is R_{col} and R_{col}=Rₛ (L−Pw)/W, wherein Rₛ is the sheet resistance. Each column has essentially the resistance R_{col}. The N columns are electrically parallel so that the total heater resistance R_{H}=Rₛ (L−Pw)/(W N).

As an example, if the resistive material rectangle is a printed carbon rectangle with Rₛ=30 Ω/square and (L−Pw)/W=15, R_{col}=450Ω. If N=45, R_{H}=10Ω. A 12-volt battery can supply about 14 Watts of power to the heater which is an appropriate amount for a wearable heater and for other articles with a R_{H} of about 10Ω.

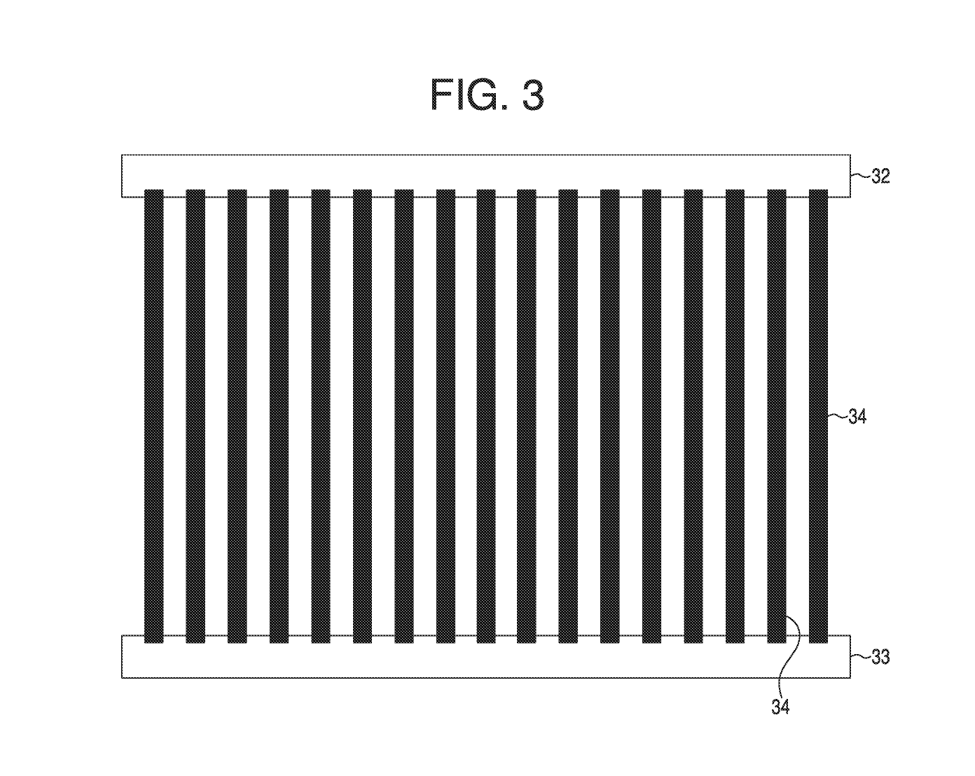

FIG. 3 shows columns of printed resistive material for use in another embodiment of a heater, wherein the heater contains a substrate with two parallel bus bars 32 and 33, and an array of parallel printed columns 34 of resistive material between the bus bars 32 and 33. The printed columns of resistive material 34 are shown orthogonal to the bus bars 32 and 33.

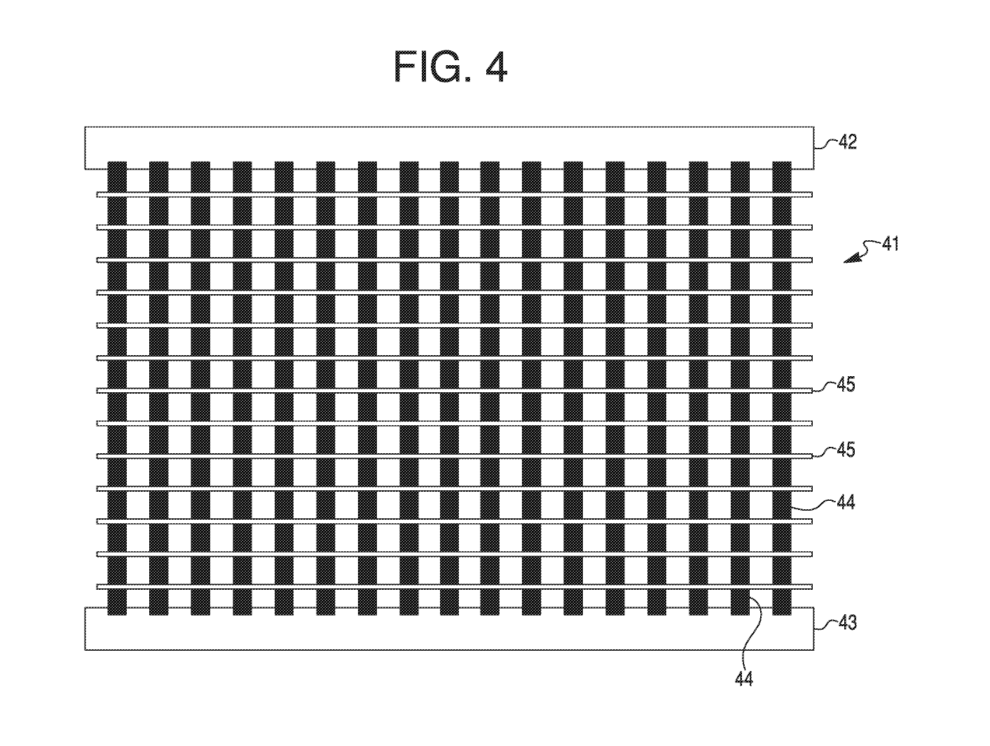

FIG. 4 illustrates an embodiment of a printed heater 41, the heater comprising a substrate with two parallel bus bars 42 and 43, an array of parallel printed columns 44 of resistive material between the bus bars 42 and 43 and orthogonal to the bus bars, and rows 45 of conductive material orthogonal to the columns 43 and spaced equidistant from one another and spanning all the columns. The bus bars 42 and 43 are shown printed onto the substrate first, followed by the resistive material columns 44 and then followed by the rows 45 of conductive material.

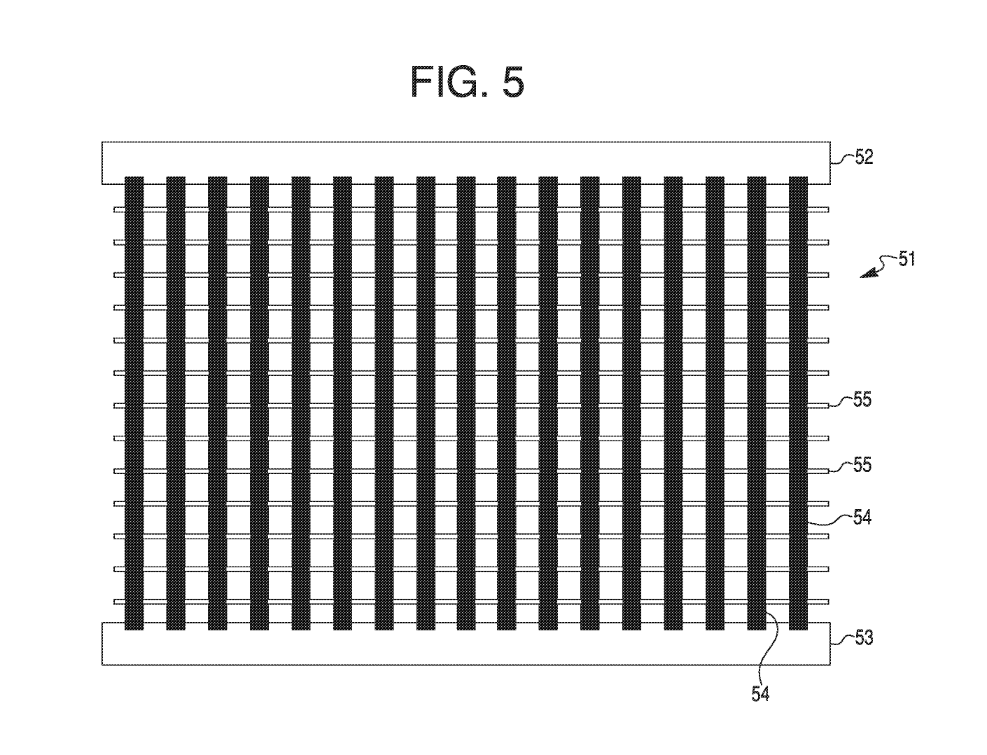

FIG. 5 illustrates an embodiment of a printed heater 51, the heater comprising a substrate with two parallel bus bars 52 and 53, an array of parallel printed columns 54 of resistive material between the bus bars 52 and 53 and orthogonal to the bus bars, and rows 55 of conductive material orthogonal to the columns 54 and spaced equidistant from one another and spanning all the columns. The bus bars 52 and 53 and the rows 55 of conductive material are shown printed onto the substrate first followed by the resistive material columns 54.

As indicated previously, the failure of a portion of a resistive column would eliminate the ability of the entire column to heat were it not for the rows of conductive material connecting all the columns of resistive material. The order of the deposition of the columns of resistive material and the rows of conductive material makes no difference. If a portion of a resistive column fails and open-circuits, the adjacent conductive material rows carry the current around the failed resistive material portion. The resistive material in the column outside the failed portion will continue to heat.

### EXAMPLES

### Example 1

Rectangular heaters with the overall dimensions of 240 mm wide by 160 mm high and with the configuration of FIGS. 1 and 2 have been fabricated and tested. In the description of the Example, reference is made to the component numbers in those Figures. The resistive material rectangles 11 are made of printed carbon paste, DuPont™ 7102 (DuPont Co., Wilmington, Del.) with a sheet resistivity of 22 Ohms/square. The silver for the printed silver bus bars and rows is DuPont™ 5025 (DuPont Co., Wilmington, Del. with sheet resistivity of 0.025 Ohms/square. The substrate was polyethylene terephthalate (PET) with a thickness of 0.2 mm.

Referring to the dimensional parameters of FIG. 2, the width of the resistive material rectangles (14) is 4 mm, the effective length, Leff (16) of the resistive material rectangle is 4 mm. The width w of the conductive row (15) is 3 mm, and the space (13) between the resistive rectangles is 1 mm. The distance, d, between columns (17) is 1 mm. The resistance of each resistive material rectangle, R_{rect}=Rₛ×L_{eff}/W so that R_{rect}=22 Ohms. The number of resistive rectangles per column M=19 and the number of columns of resistive rectangles N=48. The total heater resistance is 8.7 Ohms. The printed heaters of this Example were laboratory tested for electrical and thermal properties. The thermal tests were carried out with the heater placed in open air in ambient conditions. The maximum temperatures achieved versus applied voltage are shown in Table I.

TABLE I

| Applied Voltage | Max. Temperature from |
|---|---|
| (Volts) | Infrared Camera (° C.) |
| 0 | 21 |
| 6 | 32 |
| 8 | 41 |
| 10 | 44 |
| 12 | 60 |
| 13 | 64 |
| 15 | 76 |

### Example 2

Using the heater of Example 1, one of the carbon resistive rectangles toward the middle of the heater was purposefully damaged so that the rectangle became open circuit. A heating test was conducted using a thermal imaging camera and it was found that the damaged rectangle was the only carbon resistive rectangle that did not heat. All the other carbon resistive rectangles including those surrounding the damaged rectangle heated normally. This shows the damage-tolerant nature of heater of this invention.

What is claimed is:

1. An article containing a heater, the heater comprising:
a) a substrate;
b) two printed bus bars;
c) an array of printed resistive material areas of essentially the same shape arranged in columns between the two bus bars with spaces between adjacent resistive material areas in a column and with a separation between adjacent columns, wherein the first resistive material area in each column is contiguous to one bus bar and the last resistive material area in each column is contiguous to the other bus bar; and
d) an array of printed conductive material areas, wherein each printed conductive material area is positioned to fill the spaces between and overlap and be contiguous to adjacent pairs of resistive material areas in two or more columns, wherein there is a conductive material area in every space between resistive material areas in a column and wherein the conductive material areas and the bus bars can be printed onto the substrate before or after the resistive material areas.

2. The article of claim 1, wherein the array of printed resistive material areas are essentially the same shape and are arranged in parallel columns, wherein there are M resistive material areas in each column, wherein adjacent resistive material areas in each column are numbered i and i+1 in the same order, where i ranges from 1 to M−1, and wherein there are M−1 printed conductive material areas, wherein a printed conductive material area is positioned to fill each space between and overlap and be contiguous to the adjacent pair of resistive material areas i and i+1 in all the columns, where i ranges from 1 to M−1.

3. The article of claim 2, wherein the two printed bus bars are parallel, wherein the columns of resistive areas are orthogonal to the bus bars and the columns are essentially identical so that the i^{th} resistive material areas in the various columns form a row as do the spaces above and below the resistive material areas and these rows are orthogonal to the columns, wherein the M−1 printed conductive material areas are M−1 rows of printed conductor with a width w greater than the space between adjacent resistive material areas, and wherein the M−1 rows of printed conductor are orthogonal to the columns and a printed conductor row is positioned to overlap each row of spaces.

4. The article of claim 3, wherein each individual resistive material area is in the form of a rectangle with width W and effective length L_{eff}, each resistive material rectangle has essentially the same sheet resistance Rₛ, the spaces between adjacent pairs of resistive material rectangles in a column are essentially identical, and wherein there are N columns and there is a separation d between adjacent columns.

5. The article of claim 4, wherein d is between 0.3 and 10 times the width W of a resistive material rectangle.

6. The article of claim 4, wherein the heater resistance R_{H} is (L_{eff} M)/(W N).

7. The article of claim 4, wherein the M−1 rows of conductive material are equidistant from one another.

8. The article of claim 1, wherein the printed bus bars are silver bus bars, the printed resistive material is carbon, and the printed conductive areas are silver.

9. The article of claim 1, wherein the printed bus bars are copper bus bars, the printed resistive material is carbon, and the printed conductive areas are copper.

10. The article of claim 1, wherein the article is a wearable garment.

11. The article of claim 10, wherein the substrate is permeable and the exposed permeable substrate in the separations between adjacent columns renders the heater breathable.

12. An article containing a heater, the heater comprising:
a) a substrate;
b) two printed bus bars;
c) an array of printed columns of resistive material between the two bus bars with a separation between adjacent columns, wherein the top of each column is contiguous to one bus bar and the bottom of each column is contiguous to the other bus bar; and
d) an array of printed rows of conductive material spaced at intervals across the columns of resistive material, wherein the bus bars and the conductive material rows can be printed onto the substrate before or after the resistive material columns.

13. The article of claim 12, wherein the two printed bus bars are parallel, wherein the columns of resistive material are orthogonal to the two bus bars; and wherein the rows of conductive material are orthogonal to the columns of resistive material.

14. The article of claim 12, wherein each individual resistive material column has a width W and a length L, each resistive material column has essentially the same sheet resistance Rₛ, and there are P rows of conductive material each of width w, and wherein there are N columns and there is a separation d between adjacent columns.

15. The article of claim 14, wherein d is between 0.3 and 10 times the width W of a resistive material column.

16. The article of claim 14, wherein the heater resistance R_{H} is Rₛ(L−Pw)/(W N).

17. The article of claim 14, wherein the P rows of conductive material are equidistant from one another.

18. The article of claim 12, wherein the printed bus bars are silver bus bars, the printed resistive material is carbon and the printed conductive rows are silver.

19. The article of claim 12, wherein the printed bus bars are copper bus bars, the printed resistive material is carbon and the printed conductive rows are copper.

20. The article of claims 12, wherein the article is a wearable garment.

21. The article of claim 20, wherein the substrate is permeable and the exposed permeable substrate in the separations between adjacent columns renders the heater breathable.
